(19) United States
(12) Patent Application Publication
(10) Pub. No.: US 2016/0133818 A1
(43) Pub. Date: May 12, 2016

(54) THERMOELECTRIC GENERATION STRUCTURE FOR VEHICLE

(71) Applicant: HYUNDAI MOTOR COMPANY, Seoul (KR)

(72) Inventors: Su Jung Noh, Seoul (KR); In Woong Lyo, Suwon (KR); Tae Won Lee, Incheon (KR); Kyong Hwa Song, Seoul (KR); Hong Kil Baek, Seoul (KR); Jin Woo Kwak, Gyeongsan (KR); In Chang Chu, Seoul (KR); Gyung Bok Kim, Seoul (KR); Seung Woo Lee, Seoul (KR); Han Saem Lee, Seoul (KR)

(21) Appl. No.: 14/659,647

(22) Filed: Mar. 17, 2015

(30) Foreign Application Priority Data
Nov. 7, 2014 (KR) 10-2014-0154699

(51) Int. Cl. H01L 37/00

(52) U.S. Cl. CPC H01L 37/00

(57) ABSTRACT

A thermoelectric generation structure for a vehicle is provided. The structure includes an exhaust manifold into which exhaust gas is introduced and a cover that is disposed within the exhaust manifold and provided with a cooling water microchannel to perform cooling. A magnetic thermoelectric material is mounted between the cover and the exhaust manifold to generate electricity. Additionally, the magnetic thermoelectric material having an adjustable size and shape is used in the thermoelectric generation device by being mounted in the exhaust manifold of the vehicle to minimize the weight and volume to improve the marketability. The electricity is generated by the magnetic thermoelectric material using the spin seebeck phenomenon to improve the fuel efficiency.

### CROSS-REFERENCE TO RELATED APPLICATION

This application is based on and claims the benefit of priority to Korean Patent Application No. 10-2014-0154699, filed on Nov. 7, 2014 in the Korean Intellectual Property Office, the disclosure of which is incorporated herein in its entirety by reference.

### TECHNICAL FIELD

The present disclosure relates to a thermoelectric generation structure for a vehicle, and more particularly, to a thermoelectric generation structure for a vehicle in which a thermoelectric element is mounted in high-temperature heat source parts such as an exhaust system and an engine part of the vehicle along with a cooling system and the thermoelectric element moves electrons based on a temperature gradient to generate electricity, to improve fuel efficiency and adjust a size and a shape of the thermoelectric element.

### BACKGROUND

Generally, many thermoelectric generation systems for a vehicle which have been currently developed are applied to an exhaust pipe and do not emit a high output value using low-temperature exhaust gas heat. Meanwhile, for the thermoelectric element, the greater the temperature difference between a high temperature part and a low temperature part, the greater the output.

However, since a plurality of n/p type semiconductor pellets are required to be mounted in a module, a size and a shape of the existing commercial thermoelectric generation element are almost defined or fixed and thus the commercial thermoelectric generation element may be difficult to apply to a curved exhaust manifold. In other words, due to a shape difference between a curved manifold part and a flat commercial element, it may be difficult to mount the commercial element. Further, several commercial elements are required to be mounted for a high output but has a limitation in mounting due to a limited space of the manifold part.

Further, for the existing thermoelectric generation element using a non-magnetic material, the size and number of n/p type semiconductor pellets configuring the thermoelectric generation element have a substantial effect on improvement in an output and therefore it may not be possible to change the size and shape of the thermoelectric generation element and the thermoelectric generation element is required to be mounted to have a uniform contact area between the thermoelectric generation element and the manifold to properly obtain an output, and therefore it may be difficult to mount the commercial element.

### SUMMARY

The present disclosure provides a thermoelectric generation structure for a vehicle in which a thermoelectric element is mounted in high-temperature heat source parts such as an exhaust system and an engine part of the vehicle along with a cooling system and the thermoelectric element moves electrons based on a temperature gradient to generate electricity to improve fuel efficiency and freely adjust a size and a shape of the thermoelectric element.

According to an exemplary embodiment of the present disclosure, a thermoelectric generation structure for a vehicle may include: an exhaust manifold into which exhaust gas is introduced; a cover disposed within the exhaust manifold and provided with a cooling water microchannel to perform cooling; and a magnetic thermoelectric material mounted between the cover and the exhaust manifold to generate electricity.

The magnetic thermoelectric material and the cover may be coupled by soldering. The magnetic thermoelectric material may include an electrode layer to generate electricity and the electrode layer may be connected to a power supply unit of the vehicle. The electrode layer may be mounted over the magnetic thermoelectric material. Alternatively, the electrode layer may be mounted under the magnetic thermoelectric material. The electrode layer may also be mounted over the magnetic thermoelectric material and may be connected to the soldering.

According to another exemplary embodiment of the present disclosure, a thermoelectric generation structure for a vehicle may include: an exhaust manifold into which exhaust gas is introduced; a cover configured disposed within the exhaust manifold, provided with a cooling water microchannel to perform cooling, and provided with a groove; and a magnetic thermoelectric material configured to be inserted into the groove to be mounted between the cover and the exhaust manifold and generate electricity.

The groove and the magnetic thermoelectric material may be coupled by soldering. The magnetic thermoelectric material may include an electrode layer to generate electricity and the electrode layer may be connected to a power supply unit of the vehicle. The electrode layer may be mounted under the magnetic thermoelectric material. Alternatively, the electrode layer may be mounted over the magnetic thermoelectric material and may be connected to the soldering.

According to still another exemplary embodiment of the present disclosure, a thermoelectric generation structure for a vehicle may include: an exhaust manifold into which exhaust gas is introduced; a cover disposed within the exhaust manifold and provided with a groove; and a magnetic thermoelectric material configured to be inserted into the groove and to generate electricity. An electrode layer generating electricity may be disposed over the magnetic thermoelectric material and the electrode layer may be connected to a power supply unit of the vehicle.

According to still yet another exemplary embodiment of the present disclosure, a thermoelectric generation structure for a vehicle may include: an exhaust manifold into which exhaust gas is introduced; a cover disposed within the exhaust manifold and provided with a cooling water microchannel to perform cooling; a magnetic thermoelectric material mounted on a bottom surface of the cover to generate electricity; and an electrode layer disposed under the magnetic thermoelectric material and connected to a power supply unit of the vehicle to generate electricity.

According to further still yet another exemplary embodiment of the present disclosure, a thermoelectric generation structure for a vehicle may include: an exhaust manifold into which exhaust gas is introduced; a cover having a bottom surface provided with a water cooling layer to perform cooling; a magnetic thermoelectric material mounted within the exhaust manifold to generate electricity; and an electrode layer disposed between the magnetic thermoelectric material and the water cooling layer and connected to a power supply unit of the vehicle to generate electricity.

### BRIEF DESCRIPTION OF THE DRAWINGS

The above and other objects, features and advantages of the present disclosure will be more apparent from the following detailed description taken in conjunction with the accompanying drawings.

FIG. 1 is an exemplary diagram illustrating a thermoelectric generation structure for a vehicle according to an exemplary embodiment of the present disclosure;

FIGS. 2 and 3 are cross-sectional views illustrating a thermoelectric generation structure for a vehicle according to a first exemplary embodiment of the present disclosure;

FIG. 4 is an exemplary diagram illustrating an electrode layer of the thermoelectric generation structure for a vehicle according to the first exemplary embodiment of the present disclosure;

FIGS. 5 and 6 are exemplary cross-sectional views illustrating the electrode layer of the thermoelectric generation structure for a vehicle according to the first exemplary embodiment of the present disclosure;

FIG. 7 is an exemplary diagram illustrating the electrode layer of the thermoelectric generation structure for a vehicle according to the first exemplary embodiment of the present disclosure;

FIGS. 8 and 9 are exemplary cross-sectional views illustrating the electrode layer of the thermoelectric generation structure for a vehicle according to the first exemplary embodiment of the present disclosure;

FIG. 10 is an exemplary diagram illustrating the electrode layer of the thermoelectric generation structure for a vehicle according to the first exemplary embodiment of the present disclosure;

FIGS. 11 to 13 are exemplary cross-sectional views illustrating a thermoelectric generation structure for a vehicle according to a second exemplary embodiment of the present disclosure;

FIGS. 14 to 16 are exemplary cross-sectional views illustrating an electrode layer of the thermoelectric generation structure for a vehicle according to the second exemplary embodiment of the present disclosure;

FIGS. 17 to 19 are exemplary cross-sectional views illustrating a thermoelectric generation structure for a vehicle according to a third exemplary embodiment of the present disclosure;

FIGS. 20 to 21 are exemplary cross-sectional views illustrating a thermoelectric generation structure for a vehicle according to a fourth exemplary embodiment of the present disclosure;

FIGS. 22 and 23 are exemplary cross-sectional views illustrating a thermoelectric generation structure for a vehicle according to a fifth exemplary embodiment of the present disclosure; and

FIG. 24 is an exemplary cross-sectional view illustrating each type of a magnetic thermoelectric material in the thermoelectric generation structure for a vehicle according to the exemplary embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and ^{the} are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/of” includes any and all combinations of one or more of the associated listed items.

A first exemplary embodiment of the present disclosure will be described in detail with reference to the accompanying drawings.

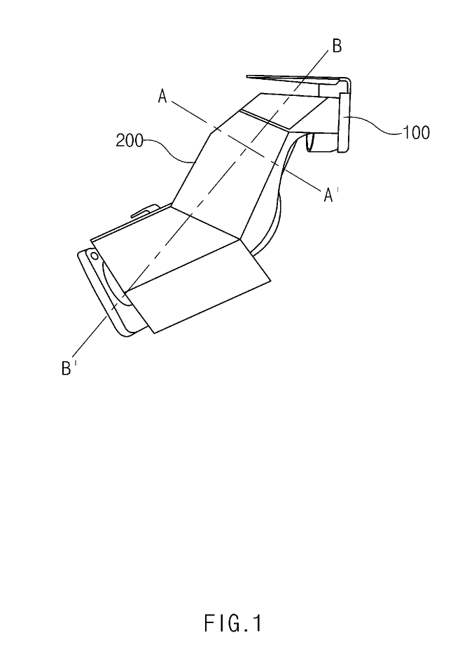

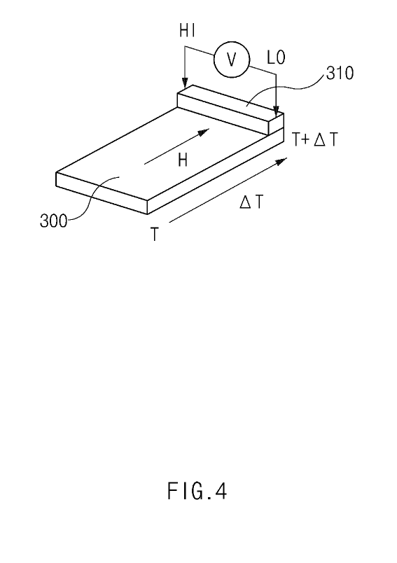

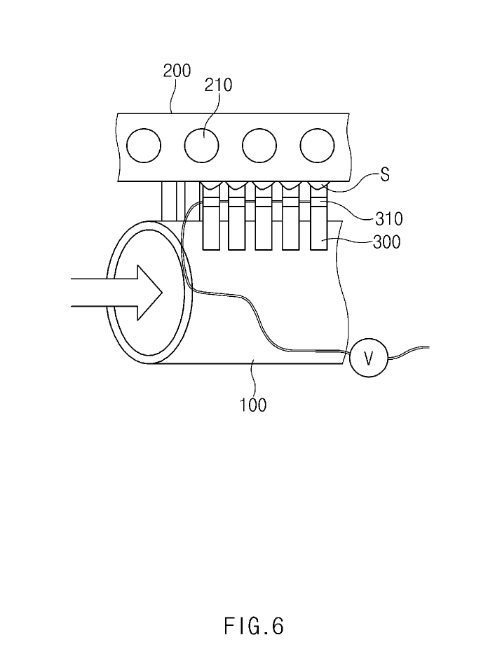

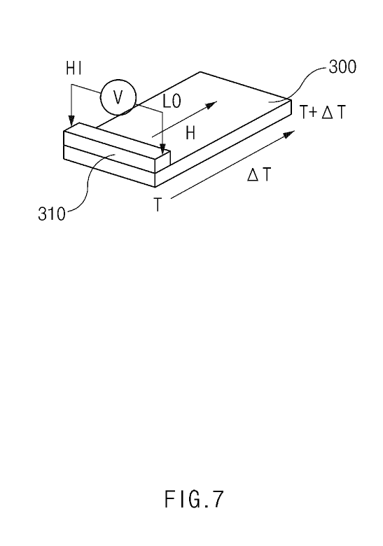

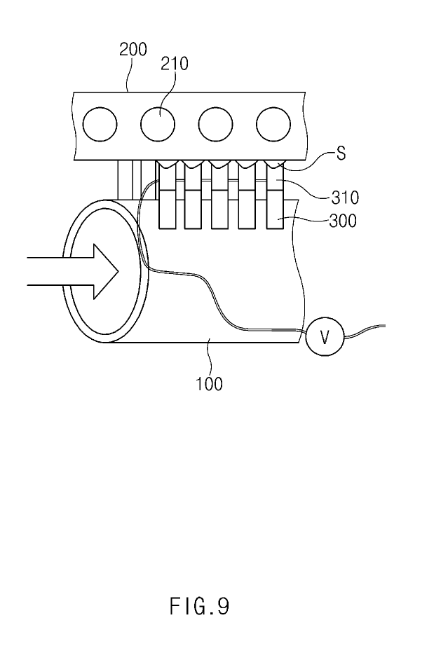

As illustrated in FIGS. 1 to 9, a thermoelectric generation structure for a vehicle according to an exemplary embodiment of the present disclosure may include an exhaust manifold 100, a cover 200 on which a cooling water microchannel 210 may be disposed, and a magnetic thermoelectric material 300 configured to generate electricity.

As illustrated in FIGS. 1 to 4, the exhaust manifold 100 may be a high-temperature heat source part of a vehicle into which exhaust gas is introduced and the present disclosure may be applied to the exhaust manifold 100 and an engine part. The cover 200 may be disposed within the exhaust manifold 100 and may include a cooling water microchannel 210 to perform cooling. In particular, the cover 200 may include a plurality of cooling water microchannels 210 mounted on the cover 200 at a predetermined interval. The magnetic thermoelectric material 300 may be mounted between the cover 200 and the exhaust manifold 100 to generate electricity using a spin seebeck phenomenon of the magnetic material, thereby implementing thermoelectric generation.

Meanwhile, according to the exemplary embodiment of the present disclosure, the magnetic thermoelectric material 300 may be formed of a single material, not n/p type semiconductor and therefore a size and a shape of an element may be adjusted and the spin seebeck phenomenon within the magnetic thermoelectric material 300 due to a temperature difference is a unique nature of a magnetic material and various magnetic materials may be applied.

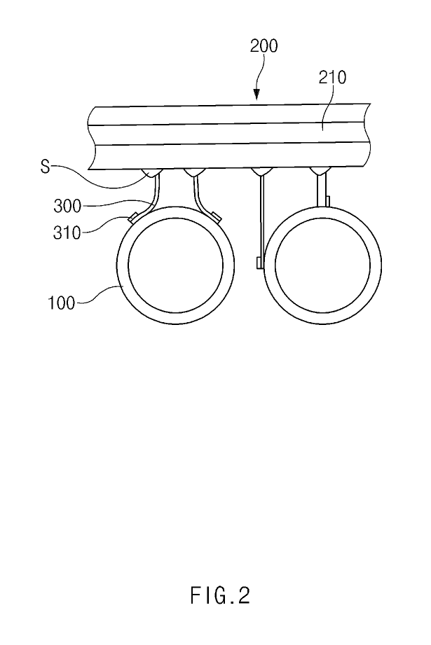

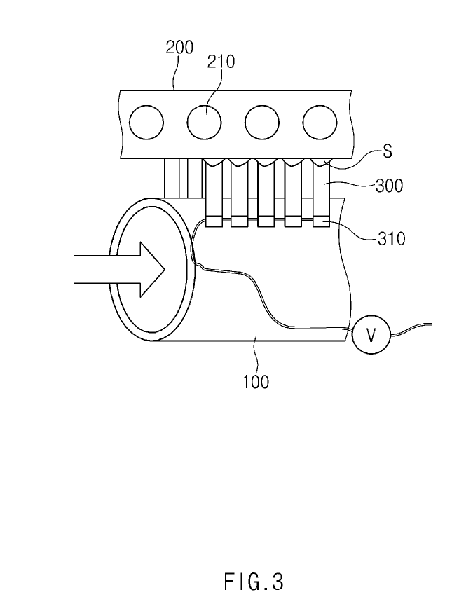

In particular, the magnetic thermoelectric material 300 and the cover 200 may be coupled by soldering S. Further, the magnetic thermoelectric material 300 may include an electrode layer 310 which may be configured to generate electricity, in which the electrode layer 310 may be connected to a power supply unit v of the vehicle to allow the magnetic thermoelectric material 300 to generate electricity. As illustrated in FIGS. 2 and 3, the electrode layer 310 may be mounted at a hot side portion which is a lower portion of the magnetic thermoelectric material 300 and may be adjacent to the exhaust manifold 100.

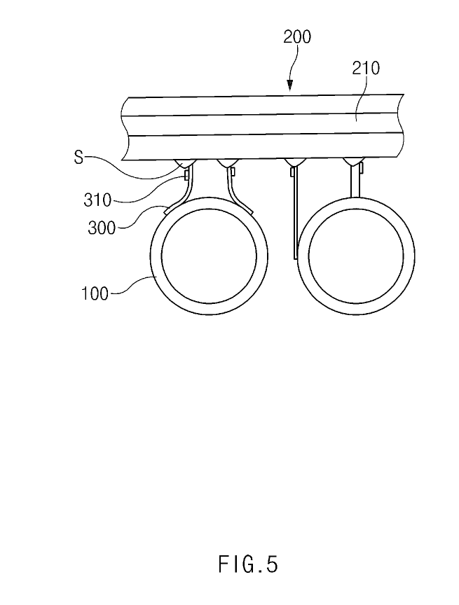

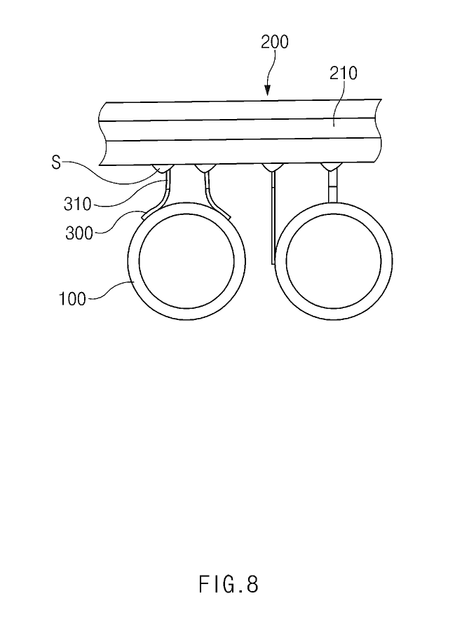

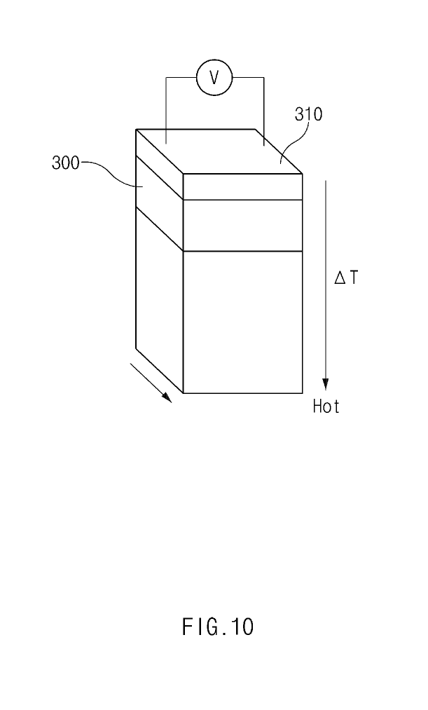

Meanwhile, according to the exemplary embodiment of the present disclosure, as illustrated in FIGS. 5 to 7, the electrode layer 310 may be mounted over the magnetic thermoelectric material 300 and thus may also be mounted at a cold side portion, spaced apart from the exhaust manifold 100. Further, according to the exemplary embodiment of the present disclosure, as illustrated in FIGS. 8 to 10, one end (e.g., a first end) of the electrode layer 310 may be mounted over the magnetic thermoelectric material 300 and the other end (e.g., a second end) may be connected to the soldering S.

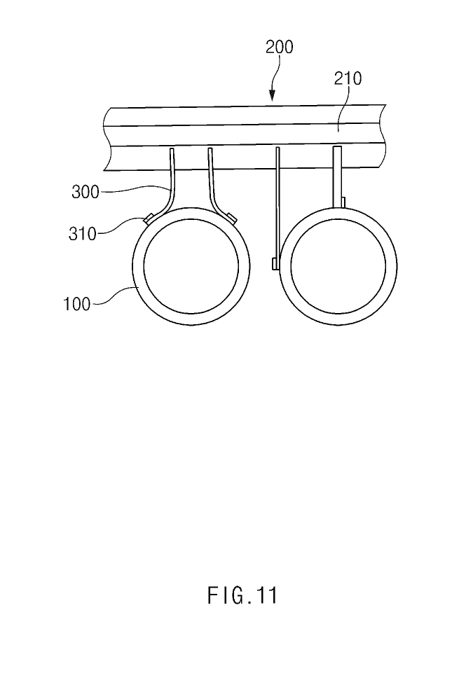

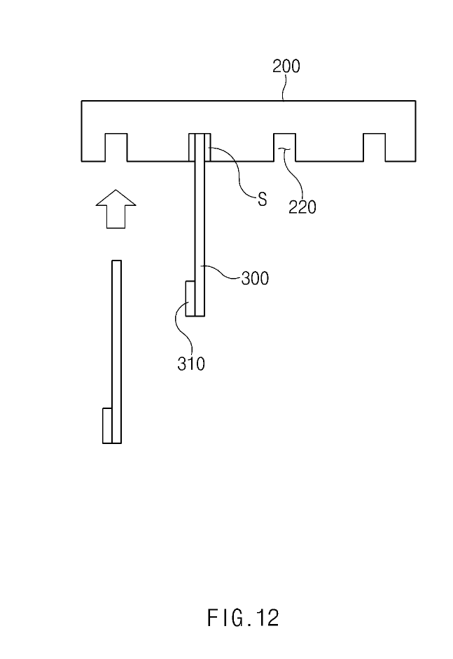

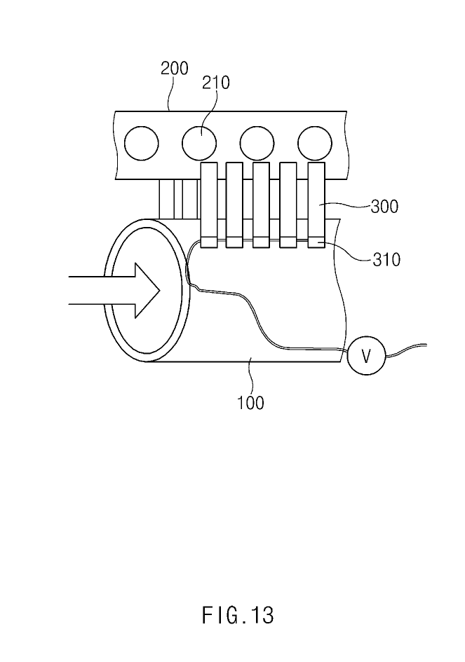

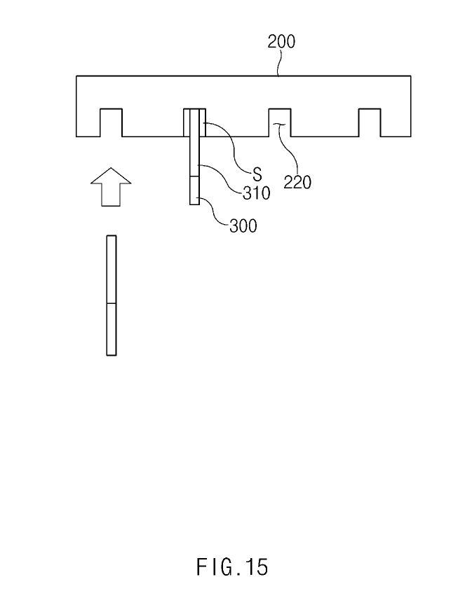

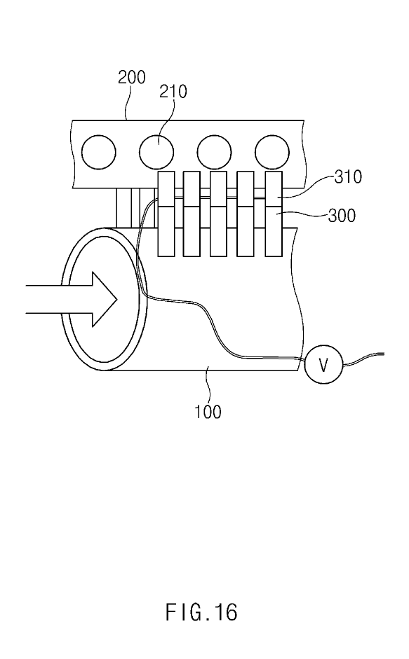

A second exemplary embodiment of the present disclosure will be described in detail with reference to the accompanying drawings. As illustrated in FIGS. 11 to 16, a thermoelectric generation structure for a vehicle according to an exemplary embodiment of the present disclosure may include the exhaust manifold 100, the cover 200 on which a cooling water microchannel 210 is mounted and a groove 220 is formed, and the magnetic thermoelectric material 300 configured to generate electricity.

As illustrated in FIGS. 11 to 14, the exhaust manifold 100 may be the high-temperature heat source part of the vehicle into which the exhaust gas is introduced and the present disclosure may be applied to the exhaust manifold 100 and the engine part. The cover 200 may be disposed within the exhaust manifold 100 and may include the cooling water microchannel 210 to perform cooling and a lower potion thereof may include the plurality of grooves 220.

In particular, the plurality of cooling water microchannels 210 may be mounted on the cover 200 at a predetermined interval (e.g., spaced apart at predetermined intervals). The magnetic thermoelectric material 300 may be inserted into the groove 220 of the cover 200 to be mounted between the cover 200 and the exhaust manifold 100 and may be configured to generate electricity using the spin seebeck phenomenon of the magnetic material, thereby implementing the thermoelectric generation. The groove 220 and the magnetic thermoelectric material 300 which are formed on the cover 200 may be coupled by the soldering S.

Further, the magnetic thermoelectric material 300 may include an electrode layer 310 which may generate electricity, in which the electrode layer 310 may be connected to a power supply unit v of the vehicle to allow the magnetic thermoelectric material 300 to generate electricity. In particular, as illustrated in FIGS. 11 to 13, the electrode layer 310 may be mounted at the hot side portion which is the lower portion of the magnetic thermoelectric material 300 and may be adjacent to the exhaust manifold 100.

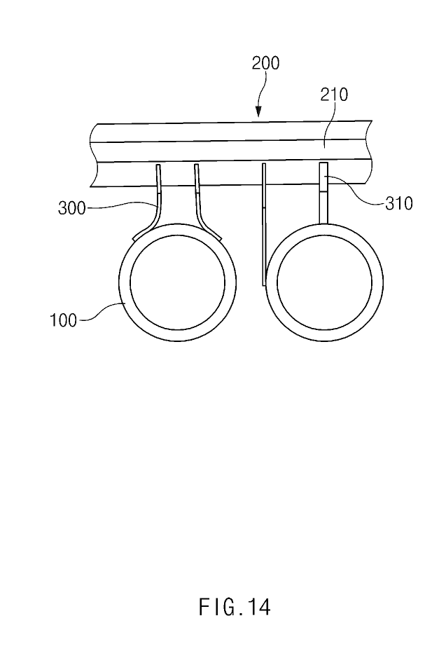

Meanwhile, according to the exemplary embodiment of the present disclosure, as illustrated in FIGS. 14 to 16, the electrode layer 310 may be mounted over the magnetic thermoelectric material 300 and thus may be mounted at a cold side portion, spaced apart from the exhaust manifold 100 and may be connected to the soldering S.

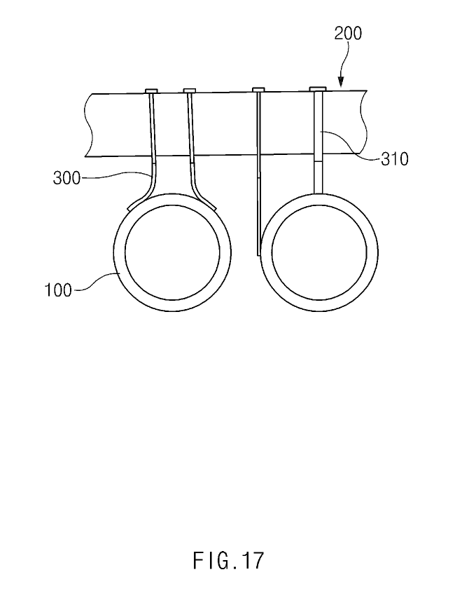

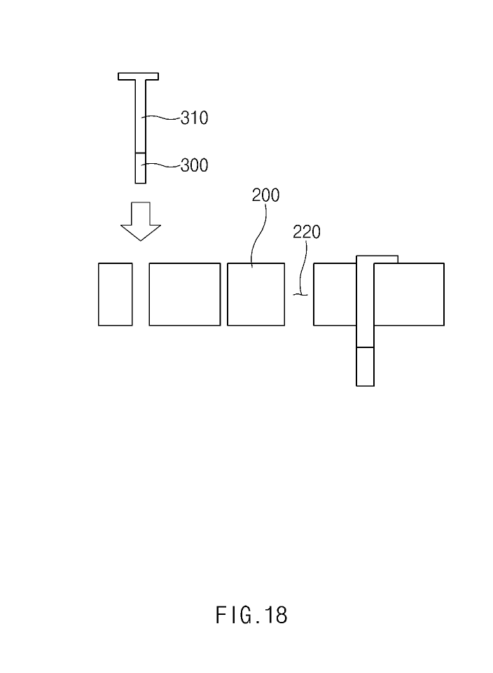

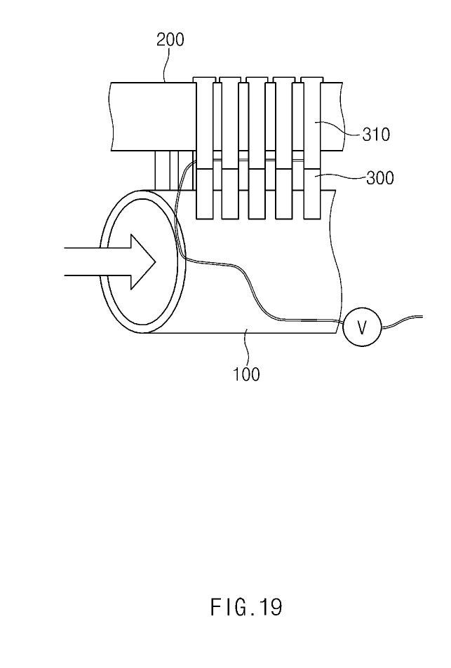

A third exemplary embodiment of the present disclosure will be described in detail with reference to the accompanying drawings. As illustrated in FIGS. 17 to 19, a thermoelectric generation structure for a vehicle according to an exemplary embodiment of the present disclosure may include the exhaust manifold 100, the cover 200 on which the groove 220 is formed, and the magnetic thermoelectric material 300 configured to generate electricity. As illustrated in FIGS. 17 to 19, the exhaust manifold 100 may be the high-temperature heat source part of the vehicle into which the exhaust gas is introduced and the present disclosure may be applied to the exhaust manifold 100 and the engine part.

The cover 200 may be disposed within the exhaust manifold 100 and may be penetrated with the plurality of grooves 220. The magnetic thermoelectric material 300 may be penetratedly inserted into the groove 220 of the cover 200 to connect between the cover 200 and the exhaust manifold 100 and may be configured to generate electricity using the spin seebeck phenomenon of the magnetic material, thereby implementing the thermoelectric generation. In particular, according to the third exemplary embodiment of the present disclosure, the cooling by air cooling through the groove 220 formed on the cover 200 may be performed. Further, an upper portion of the magnetic thermoelectric material 300 may be provided with the electrode layer 310 which may be configured to generate electricity, in which the electrode layer 310 may be connected to the power supply unit v of the vehicle to allow the magnetic thermoelectric material 300 to generate electricity.

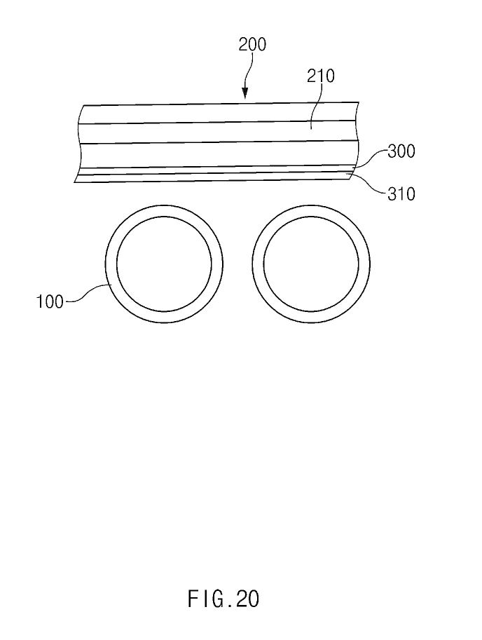

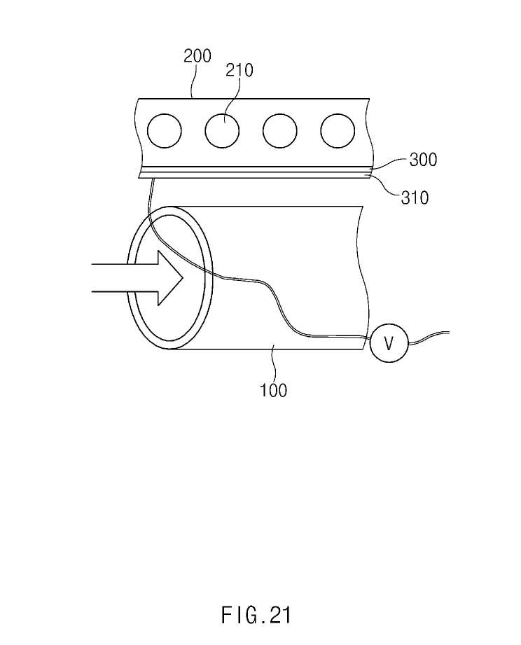

A fourth exemplary embodiment of the present disclosure will be described in detail with reference to the accompanying drawings. As illustrated in FIGS. 20 and 21, a thermoelectric generation structure for a vehicle according to an exemplary embodiment of the present disclosure may include the exhaust manifold 100, the cover 200 on which the cooling water microchannel 210 is mounted, the magnetic thermoelectric material 300 configured to generate electricity, and the electrode layer 310 which may be configured to generate electricity.

As illustrated in FIGS. 20 and 21, the exhaust manifold 100 may be the high-temperature heat source part of the vehicle into which the exhaust gas is introduced and the present disclosure may be applied to the exhaust manifold 100 and the engine part. The cover 200 may be disposed within the exhaust manifold 100 and may include the cooling water microchannel 210 to perform cooling. In particular, the plurality of cooling water microchannels 210 may be mounted on the cover 200 at a predetermined interval.

The magnetic thermoelectric material 300 may be mounted on a bottom surface of the cover 200 to generate electricity using a spin seebeck phenomenon of the magnetic material, thereby implementing the thermoelectric generation. The electrode layer 310 may be disposed under the magnetic thermoelectric material 300 and may be connected to the power supply unit v of the vehicle to allow the magnetic thermoelectric material 300 to generate electricity.

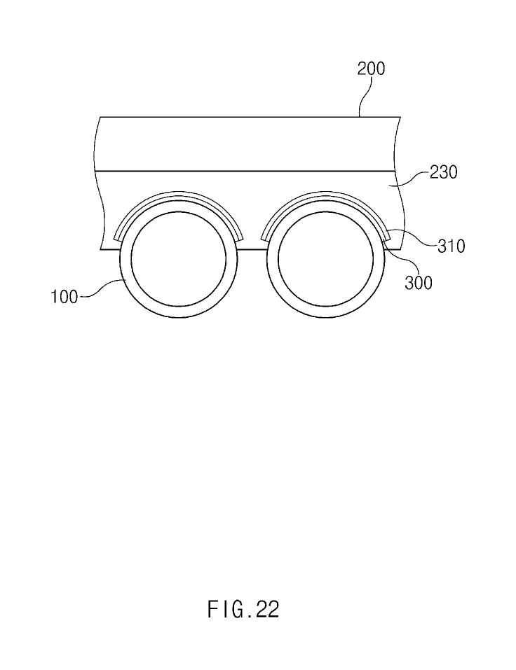

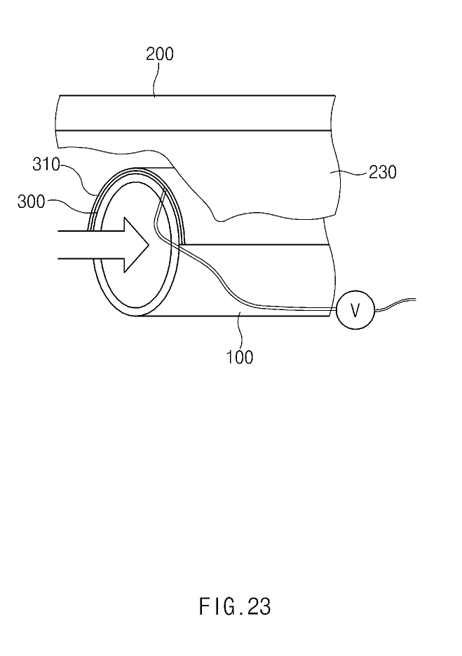

A fifth exemplary embodiment of the present disclosure will be described in detail with reference to the accompanying drawings. As illustrated in FIGS. 22 and 23, a thermoelectric generation structure for a vehicle according to an exemplary embodiment of the present disclosure may include the exhaust manifold 100, the cover 200 on which a water cooling layer 230 is formed, the magnetic thermoelectric material 300 generating electricity, and the electrode layer 310 which may be configured to generate electricity.

As illustrated in FIGS. 22 and 23, the exhaust manifold 100 may be the high-temperature heat source part of the vehicle into which the exhaust gas is introduced and the present disclosure may be applied to the exhaust manifold 100 and the engine part. The cover 200 may be disposed within the exhaust manifold 100 and a bottom surface thereof may include the water cooling layer 230 to perform cooling. In particular, the water cooling layer 230 may be formed in a curved shape and thus may correspond to the exhaust manifold 100 (e.g., the shape of the water cooling layer 230 may correspond to the shape of the exhaust manifold 100).

The magnetic thermoelectric material 300 may be mounted on a bottom surface of the cover 200 to generate electricity using a spin seebeck phenomenon of the magnetic material, thereby implementing the thermoelectric generation. The electrode layer 310 may be disposed between the magnetic thermoelectric material 300 and the water cooling layer 230 and may be connected to the power supply unit v of the vehicle to allow the magnetic thermoelectric material 300 to generate electricity.

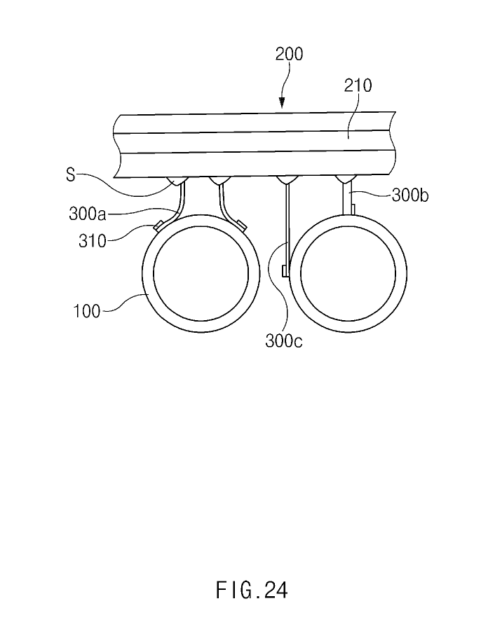

Meanwhile, according to the first to fifth exemplary embodiments of the present disclosure, as illustrated in FIG. 24, the magnetic thermoelectric material 300 may include a flexible type magnetic thermoelectric material 300a, a bulk type magnetic thermoelectric material 300b, and a wire type magnetic thermoelectric material 300c, according to application fields.

As described above, according to the exemplary embodiments of the present disclosure, the magnetic thermoelectric material of which the size and shape may be freely adjusted (e.g., adjustable size and shape) may be used in the thermoelectric generation device by being mounted within the exhaust manifold of the vehicle to minimize the weight and volume to improve the marketability and the electricity may be generated by the magnetic thermoelectric material using the spin seebeck phenomenon to improve the fuel efficiency.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A thermoelectric generation structure for a vehicle, comprising:
an exhaust manifold into which exhaust gas is introduced;
a cover disposed within the exhaust manifold and provided with a cooling water microchannel to perform cooling; and
a magnetic thermoelectric material mounted between the cover and the exhaust manifold to generate electricity.

2. The thermoelectric generation structure for a vehicle according to claim 1, wherein the magnetic thermoelectric material and the cover are coupled by soldering.

3. The thermoelectric generation structure for a vehicle according to claim 2, wherein the magnetic thermoelectric material includes an electrode layer configured to generate electricity by being connected to a power supply unit of the vehicle.

4. The thermoelectric generation structure for a vehicle according to claim 3, wherein the electrode layer is mounted over the magnetic thermoelectric material.

5. The thermoelectric generation structure for a vehicle according to claim 3, wherein the electrode layer is mounted under the magnetic thermoelectric material.

6. The thermoelectric generation structure for a vehicle according to claim 3, wherein the electrode layer is mounted over the magnetic thermoelectric material and is connected to the soldering.

7. A thermoelectric generation structure for a vehicle, comprising:
an exhaust manifold into which exhaust gas is introduced;
a cover disposed within the exhaust manifold, provided with a cooling water microchannel to perform cooling, and provided with a groove; and
a magnetic thermoelectric material inserted into the groove to be mounted between the cover and the exhaust manifold and generate electricity.

8. The thermoelectric generation structure for a vehicle according to claim 7, wherein the groove and the magnetic thermoelectric material are coupled by soldering.

9. The thermoelectric generation structure for a vehicle according to claim 8, wherein the magnetic thermoelectric material includes an electrode layer configured to generate electricity by being connected to a power supply unit of the vehicle.

10. The thermoelectric generation structure for a vehicle according to claim 9, wherein the electrode layer is mounted under the magnetic thermoelectric material.

11. The thermoelectric generation structure for a vehicle according to claim 9, wherein the electrode layer is mounted over the magnetic thermoelectric material and is connected to the soldering.

12. A thermoelectric generation structure for a vehicle, comprising:
an exhaust manifold into which exhaust gas is introduced;
a cover disposed within the exhaust manifold and provided with a groove; and
a magnetic thermoelectric material inserted into the groove and configured to generate electricity.

13. The thermoelectric generation structure for a vehicle according to claim 12, wherein an electrode layer generating electricity is disposed over the magnetic thermoelectric material and the electrode layer is connected to a power supply unit of the vehicle.

14. A thermoelectric generation structure for a vehicle, comprising:
an exhaust manifold into which exhaust gas is introduced;
a cover disposed within the exhaust manifold and provided with a cooling water microchannel to perform cooling;
a magnetic thermoelectric material mounted on a bottom surface of the cover to generate electricity; and
an electrode layer disposed under the magnetic thermoelectric material and connected to a power supply unit of the vehicle to generate electricity.

15. A thermoelectric generation structure for a vehicle, comprising:
an exhaust manifold into which exhaust gas is introduced;
a cover having a bottom surface provided with a water cooling layer to perform cooling;
a magnetic thermoelectric material mounted within the exhaust manifold to generate electricity; and
an electrode layer disposed between the magnetic thermoelectric material and the water cooling layer and connected to a power supply unit of the vehicle to generate electricity.
